(19) United States
(12) Patent Application Publication
(10) Pub. No.: US 2021/0036254 A1
(43) Pub. Date: Feb. 4, 2021

(54) LIGHT EMITTING ELEMENT AND DISPLAY DEVICE

(71) Applicant: SHARP KABUSHIKI KAISHA, Sakai City, Osaka (JP)

(72) Inventors: TATSUYA RYOHWA, Sakai City, Osaka (JP); MAKOTO IZUMI, Sakai City, Osaka (JP)

(21) Appl. No.: 16/981,953

(22) PCT Filed: Mar. 22, 2018
(86) PCT No.: PCT/JP2018/011419

§ 371 Date: Sep. 17, 2020

(51) Int. Cl. H01L 51/50; H01L 27/32; H01L 51/52; C09K 11/70; C09K 11/56; C09K 11/54; C01G 9/08; C01G 15/00

(52) U.S. Cl. CPC H01L 51/502; H01L 27/322; H01L 27/3246; H01L 51/5284; B82Y 20/00; C09K 11/565; C09K 11/54; C01G 9/08; C01G 15/00; C09K 11/70

(57) ABSTRACT

A light-emitting element is a light-emitting element provided with a cathode electrode, an anode electrode, and a light-emitting layer formed between the cathode electrode and the anode electrode. The light-emitting layer is formed by a layer including blue quantum dot phosphor particles that emit blue light, green quantum dot phosphor particles that emit green light, and red quantum dot phosphor particles that emit red light.

### TECHNICAL FIELD

The present invention relates to a light-emitting element using quantum dots (QD) and the like.

### BACKGROUND ART

Conventionally, a light-emitting element using quantum dots (QD) is known. For example, PTL 1 discloses a light-emitting element that is doped with a quantum dot light-emitting material corresponding to a color of light to be emitted, and is provided with a light-emitting layer including a plurality of sub light-emitting layers that emit light of different colors, respectively. In the technology of PTL 1, by injecting, into the light-emitting layer, a current with a current density corresponding to an arrangement of the sub light-emitting layer of a desired color, of the plurality of sub light-emitting layers, light of the desired color is emitted,

### CITATION LIST

### Patent Literature

PTL 1: Japanese Patent Publication “JP 2016-51845 A (published Apr. 11, 2016)”

### SUMMARY OF INVENTION

### Technical Problem

However, with the light-emitting element of PTL 1, there is a problem in that the light-emitting element is difficult to manufacture since it is necessary to form the plurality of sub light-emitting layers as the light-emitting layer.

An object of an aspect of the present invention is to realize a light-emitting element that is easy to manufacture.

### Solution to Problem

In order to solve the problem described above, a light-emitting element according to an aspect of the present invention is a light-emitting element including a cathode electrode, an anode electrode, and a light-emitting layer formed between the cathode electrode and the anode electrode. The light-emitting layer is formed by a layer including a first quantum dot phosphor particle that emits blue light as a result of combining electrons supplied from the cathode electrode and positive holes supplied from the anode electrode, a second quantum dot phosphor particle that emits green light as a result of combining the electrons supplied from the cathode electrode and the positive holes supplied from the anode electrode, and a third quantum dot phosphor particle that emits red light as a result of combining the electrons supplied from the cathode electrode and the positive holes supplied from the anode electrode.

### Advantageous Effects of Invention

According to a light-emitting device according to an aspect of the present invention, it is possible to realize a light-emitting element that is easy to manufacture.

### BRIEF DESCRIPTION OF DRAWINGS

FIG. 1 is a cross-sectional view of a configuration of a display region of a display device according to a first embodiment.

FIG. 2 is a cross-sectional view illustrating a configuration of a light-emitting element layer provided in the display device.

FIG. 3 is a schematic diagram illustrating a configuration of a light-emitting element provided in the light-emitting element layer.

FIG. 4(a) is a cross-sectional view illustrating a structure of a blue quantum dot phosphor particle included in a light-emitting layer provided in the light-emitting element, (b) is a cross-sectional view illustrating a structure of a green quantum dot phosphor particle included in the tight-emitting layer, and (c) is a cross-sectional view illustrating a structure of a red quantum dot phosphor particle 63 included in the light-emitting layer.

FIG. 5 is a cross-sectional view illustrating a configuration of a display region of a display device according to a second embodiment.

### DESCRIPTION OF EMBODIMENTS

### First Embodiment

Hereinafter, a display device 1 and a light-emitting element 50 according to a first embodiment of the present invention will be described in detail with reference to the drawings. Hereinafter, “the same layer” means that the layer is formed in the same process (film formation process), “a lower layer” means that the layer is formed in an earlier process than the process in which the layer to compare is formed, and “an upper layer” means that the layer is formed in a later process than the process in which the layer to compare is formed.

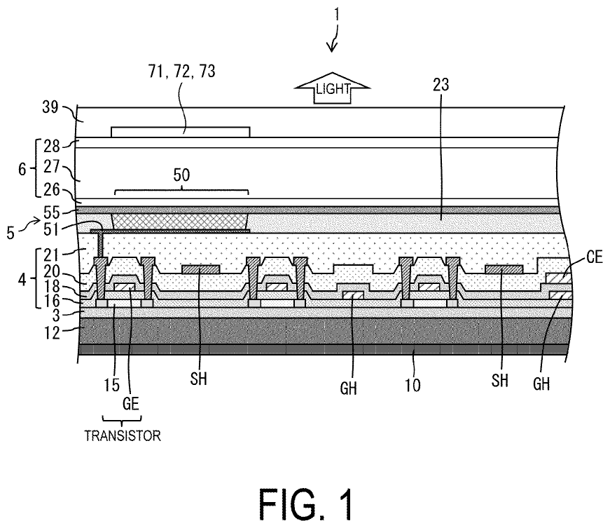

FIG. 1 is a cross-sectional view illustrating a configuration of a display region of the display device 1. As illustrated in FIG. 1, the display device 1 is provided with a lower face film 10, a resin layer 12, a barrier layer 3, a thin film transistor (TFT) layer 4, a light-emitting element layer 5, a sealing layer 6, color filters 71, 72, and 73, and a function film 39.

The lower face film 10 is a film that is bonded on the lower face of the resin layer 12 for realizing a display device with excellent flexibility, and is, for example, a PET film. The function film 39 has, for example, at least one of an optical compensation function, a touch sensor function, and a protection function.

Examples of the material of the resin layer 12 include a polyimide. A portion of the resin layer 12 can be replaced by two resin films (polyimide films, for example) and an inorganic insulating film sandwiched therebetween.

The barrier layer 3 is a layer that inhibits foreign matter, such as water and oxygen, from reaching the TFT layer 4 and the light-emitting element layer 5, and can be configured, for example, by a silicon oxide film, a silicon nitride film, or a silicon oxynitride film, or by a layered film of these, formed by CVD.

The TFT layer 4 includes a semiconductor film 15, an inorganic insulating film 16 (a gate insulating film) that is an upper layer overlying the semiconductor film 15, a gate electrode GE and a gate wiring line GH that are an upper layer overlying the inorganic insulating film 16, an inorganic insulating film 18 that is an upper layer overlying the gate electrode GE and the gate wiring line GH, a capacitance electrode CE that is an upper layer overlying the inorganic insulating film 18, an inorganic insulating film 20 that is an upper layer overlying the capacitance electrode CE, a source wiring line SH that is an upper layer overlying the inorganic insulating film 20, and a flattening film 21 (an interlayer insulating film) that is an upper layer overlying the source wiring tine SH.

The semiconductor film 15 is configured, for example, by a low-temperature polysilicon (LTPS) or an oxide semiconductor (an In—Ga—Zn—O) based semiconductor, for example), and a transistor (TFT) is configured to include the semiconductor film 15 and the gate electrode GE. In FIG. 1, the transistor having a top gate structure is illustrated, but the transistor may have a bottom gate structure.

The gate electrode GE, the gate wiring line GH, the capacitance electrode CE, and the source wiring line SH are each formed of a single layer film or a layered film of a metal, for example. The metal includes at least one of aluminum, tungsten, molybdenum, tantalum, chromium, titanium, and copper. The TFT layer 4 in FIG. 1 includes one semiconductor layer and three metal layers.

Each of the inorganic insulating films 16, 18, and 20 can be formed of, for example, a silicon oxide (SiOx) film or a silicon nitride (SiNx) film, or a layered film of these, formed using CVD. The flattening film 21 can be formed of, for example, a coatable organic material such as a polyimide or acrylic.

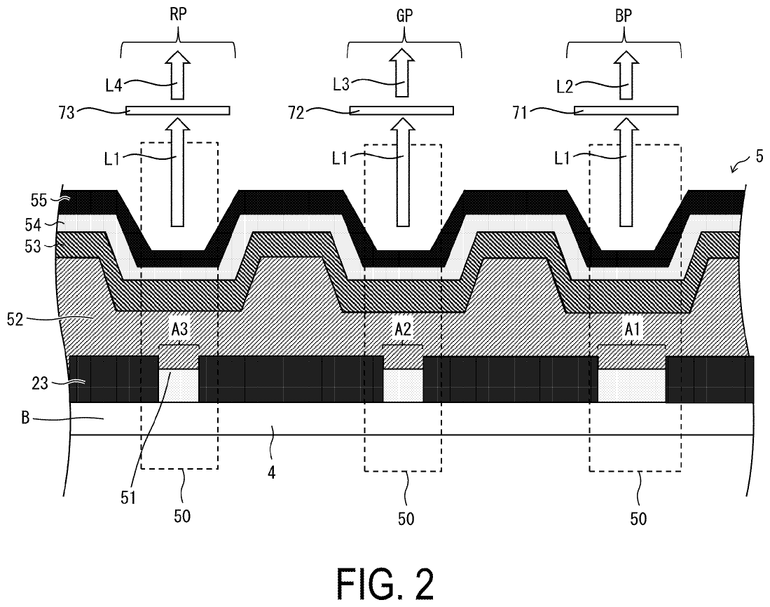

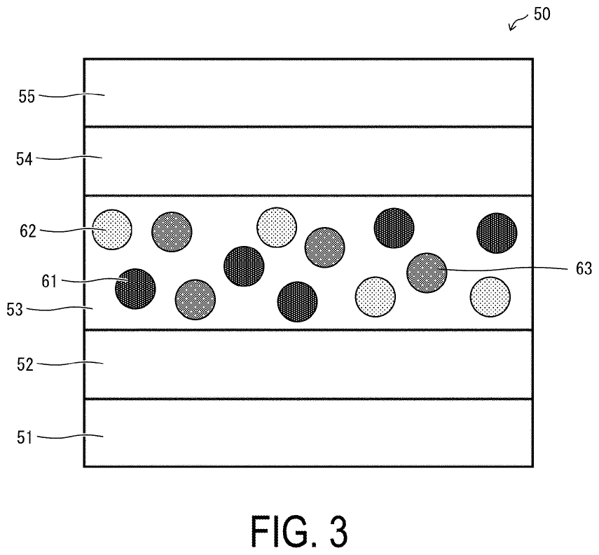

FIG. 2 is a cross-sectional view illustrating a configuration of the light-emitting element layer 5. Note that in FIG. 2, the color filters 71, 72, and 73, which will be described below, are also illustrated. FIG. 3 is a schematic view illustrating a configuration of the light-emitting element 50 provided in the light-emitting element layer 5.

As illustrated in FIG. 2, the light-emitting element layer 5 is provided with a plurality of the light-emitting elements 50. In the light-emitting element layer 5, a region corresponding to one of the light-emitting elements 50 functions as one subpixel (a red subpixel RP, a green subpixel GP, or a blue subpixel BP).

As illustrated in FIG. 3, the light-emitting element 50 is provided with an anode electrode 51, a hole transport layer (HTL) 52, a light-emitting layer 53, an electron transport layer (ETL) 54, and a cathode electrode 55 in this order from the lower side of FIG. 3 toward the upward direction.

The components from the anode electrode 51 to the cathode electrode 55 are supported by a substrate B provided below the anode electrode 51 (see FIG. 2). As an example, when manufacturing the light-emitting element 50, the anode electrode 51, the hole transport layer 52, the light-emitting layer 53, the electron transport layer 54, and the cathode electrode 55 are formed (formed as a film) in this order on the substrate B.

The anode electrode 51 is an electrode that supplies positive holes to the light-emitting layer 53. The anode electrode 51 is formed of, for example, aluminum (Al), and is a reflective electrode that reflects light emitted from the light-emitting layer 53. According to this arrangement, of the light emitted from the light-emitting layer 53, light traveling in the downward direction can be reflected by the anode electrode 51. As a result, usage efficiency of the light emitted from the light-emitting layer 53 can be improved. The anode electrode 51 can be formed by vapor deposition.

The hole transport layer 52 is a layer that transports the positive holes supplied from the anode electrode 51 to the light-emitting layer 53. The hole transport layer 52 contains a material with excellent hole transport properties. The hole transport layer 52 can be formed by vapor deposition.

The light-emitting layer 53 is formed by a layer including blue quantum dot phosphor particles (first quantum dot phosphor particles) 61, green quantum dot phosphor particles (second quantum dot phosphor particles) 62, and red quantum dot phosphor particles (third quantum dot phosphor particles) 63, each of which emits light as a result of the positive holes supplied from the anode electrode 51 and electrons supplied from the cathode electrode 55 being combined.

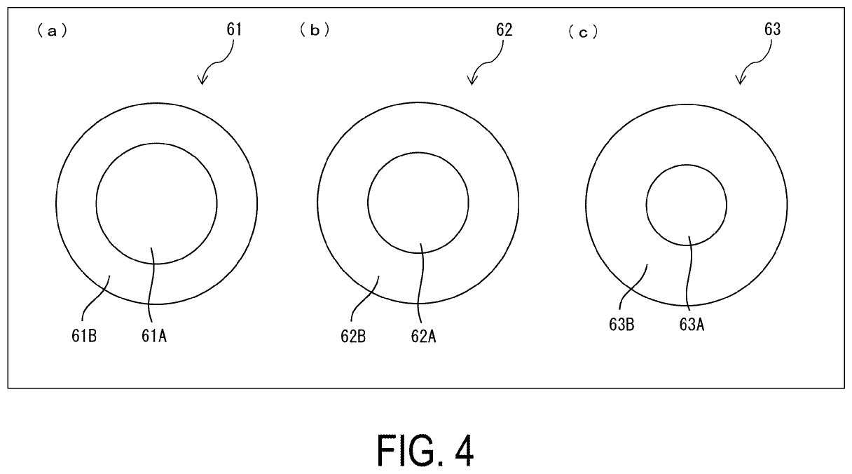

(a) of FIG. 4 is a cross-sectional view illustrating a structure of the blue quantum dot phosphor particle 61, (b) is a cross-sectional view illustrating a structure of the green quantum dot phosphor particle 62, and (c) is a cross-sectional view illustrating a structure of the red quantum dot phosphor particle 63.

As illustrated in (a) of FIG. 4, the blue quantum dot phosphor particle 61 has a core-shell structure formed by a core 61A and a shell 61B covering the periphery of the core 61A. As illustrated in (b) of FIG. 4, the green quantum dot phosphor particle 62 has a core-shell structure formed by a core 62A and a shell 62B covering the periphery of the core 62A. As illustrated in (c) of FIG. 4, the red quantum dot phosphor particle 63 has a core-shell structure formed by a core 63A and a shell 639 covering the periphery of the core 63A.

Here, it is known that the quantum dot phosphor particle emits light of different wavelengths depending on the particle diameter thereof. Specifically, with the quantum dot phosphor particle, the smaller the particle diameter, the smaller the wavelength of the emitted light. In the quantum dot phosphor particle having the core-shell structure, the wavelength of the emitted light depends on the particle diameter of the core. Therefore, as illustrated in (a) to (c) of FIG. 4, the particle diameter of the core 61A of the blue quantum dot phosphor particle 61 that emits blue light having the shortest wavelength is smaller than the particle diameter of the core 62A of the green quantum dot phosphor particle 62 and the particle diameter of the core 63A of the red quantum dot phosphor particle 63. Further, the particle diameter of the core 62A of the green quantum dot phosphor particle 62 that emits green light having the second shortest wavelength is smaller than the particle diameter of the core 63A of the red quantum dot phosphor particle 63 that emits red light having the longest wavelength.

Further, in the present embodiment, by adjusting the thicknesses of the shells 61B to 63B, the particle diameters of the blue quantum dot phosphor particle 61, the green quantum dot phosphor particle 62, and the red quantum dot phosphor particle 63 are configured to be the same as a whole. Specifically, by (1) causing the thickness (film thickness) of the shell 61B to be greater than the thickness of the shell 62B and the thickness of the shell 63B, and (2) causing the thickness of the shell 62B to be greater than the thickness of the shell 63B, the particle diameters of the blue quantum dot phosphor particle 61, the green quantum dot phosphor particle 62, and the red quantum dot phosphor particle 63 are configured to be the same as a whole. Note that in the present specification, the “same particle diameter” means that the particle diameter does not completely match, but the particle diameter is substantially the same. “The particle diameter is substantially the same” means that when forming the quantum dot phosphor particle, the particle diameter of the design value thereof is the same, but this includes variations in the particle diameter of the actually formed particles. For example, the particle diameters of the blue quantum dot phosphor particle 61, the green quantum dot phosphor particle 62, and the red quantum dot phosphor particle 63 may have an error of approximately 20%.

The blue quantum dot phosphor particle 61, the green quantum dot phosphor particle 62, and the red quantum dot phosphor particle 63 are formed of at least one material selected from the group consisting of CdS, CdSe, CdTe, ZnS, ZnSe, ZnTe, InN, InP, InAs, InSb, AlP, AlS, AlAs, AlSb, GaN, GaP, GaAs, GaSb, PbS, PbSe, Si, Ge, MgS, MgSe, and MgTe. The blue quantum dot phosphor particle 61, the green quantum dot phosphor particle 62, and the red quantum dot phosphor particle 63 may be formed of the same material or different materials, respectively. Further, the cores 61A to 63A and the shells 61B to 63B may be formed of the same material or different materials, respectively. The cores 61A to 63A according to the present embodiment are formed of InP. As a result, the light-emitting layer in a red pixel region RP, a green pixel region GP, and a blue pixel region BP, which will be described below, can be manufactured using the same material.

Note that the wavelength of the light emitted by the quantum dot phosphor particle varies depending on the materials described above, even if the particle diameter of the core is the same. Generally, a band gap of the core of the quantum dot phosphor particle is preferably in a range of from 1.8 to 2.8 eV. When the quantum dot phosphor particle is used as the red quantum dot phosphor particle 63, the band gap of the core 63A is preferably in a range of from 1.85 to 2.5 eV, when used as the green quantum dot phosphor particle 62, the band gap of the core 62A is preferably in a range of from 2.3 to 2.5 eV, and when used as the blue quantum dot phosphor particle 61, the band gap of the core 61A is preferably in a range of from 2.65 to 2.8 eV. It is sufficient that the particle diameter of the core of the quantum dot phosphor particle be designed so as to have the band gap in the range described above.

The particle diameters of the blue quantum dot phosphor particle 61, the green quantum dot phosphor particle 62, and the red quantum dot phosphor particle 63 are preferably in a range of from 0.1 nm to 100 nm, particularly preferably in a range of from 0.5 nm to 50 nm, and even more particularly preferably in a range of from 1 to 20 nm. When the particle diameters of the blue quantum dot phosphor particle 61, the green quantum dot phosphor particle 62, and the red quantum dot phosphor particle 63 are 100 nm or greater, dispersibility of each of the quantum dot phosphor particles in the light-emitting layer 53 deteriorates, and it becomes difficult to uniformly produce the light-emitting layer 53 as a film.

Note that in the present specification, a description is given using the “particle diameter” of the quantum dot phosphor particle as an index. Here, the “particle diameter” means a particle diameter assuming that the quantum dot phosphor particle is a true sphere. However, in reality, there may be a quantum dot phosphor particle that is not considered to be a true sphere. However, even when the true spherical shape of the quantum dot phosphor particle is slightly distorted, the quantum dot phosphor particle can perform substantially the same function as the quantum dot phosphor particle of the true spherical shape. Thus, the “particle diameter” in the present specification refers to a particle diameter obtained when the quantum dot phosphor particle is converted into a true sphere of the same volume.

The light-emitting layer 53 can be formed by ink-jet application.

The electron transport layer 54 is a layer that transports the electrons supplied from the cathode electrode 55 to the light-emitting layer 53. The electron transport layer 54 contains a material with excellent electron transport properties. The electron transport layer 54 can be formed by vapor deposition.

The cathode electrode 55 is an electrode that supplies the electrons to the light-emitting layer 53. The cathode electrode 55 is formed of, for example, indium tin oxide (ITO). The cathode electrode 55 is a transmissive electrode that transmits the light emitted from the light-emitting layer 53. The display device 1 is configured as a top-emitting display device that emits the light emitted from the light-emitting layer 53 in the upward direction.

In the light-emitting element 50, by applying a forward direction voltage between the anode electrode 51 and the cathode electrode 55 (setting the anode electrode 51 to a potential higher than that of the cathode electrode 55), (i) the electrons can be supplied from the cathode electrode 55 to the light-emitting layer 53, and (ii) the positive holes can be supplied from the anode electrode 51 to the light-emitting layer 53. The electrons and the positive holes supplied to the light-emitting layer 53 are combined in the blue quantum dot phosphor particle 61, the green quantum dot phosphor particle 62, or the red quantum dot phosphor particle 63 (more specifically, in the cores 61A to 63A, respectively). As a result, the blue light, the green light, and the red light are emitted from the blue quantum dot phosphor particle 61, the green quantum dot phosphor particle 62, and the red quantum dot phosphor particle 63, respectively, and by mixing the blue light, the green light, and the red light being together, white light is emitted from the light-emitting layer 53.

Here, it is known that in light emission by the quantum dot phosphor particle, light emission of the blue light is weaker than that of the green light and the red light. Thus, in the light-emitting layer 53 according to the present embodiment, the concentration of the blue quantum dot phosphor particles 61 is higher than the concentration of the green quantum dot phosphor particles 62 and the concentration of the red quantum dot phosphor particles 63. As a result, compared to a case in which the concentration of the blue quantum dot phosphor particles 61 is the same as the concentration of the green quantum dot phosphor particles 62 and the concentration of the red quantum dot phosphor particles 63, the light-emitting layer 53 can emit light closer to the white light.

As illustrated in FIG. 2, the light-emitting element layer 5 is provided with the plurality of light-emitting elements 50. In the light-emitting element layer 5, an edge of each of the anode electrodes 51 of the light-emitting elements 50 is covered by an edge cover 23, and the subpixel (the red pixel region RP, the green pixel region GP, and the blue pixel region BP to be described below) is formed by each of the light-emitting elements 50. In the light-emitting element layer 5, one pixel is formed by one of the red pixel regions RP, one of the green pixel regions GP, and one of the blue pixel regions BP.

The sealing layer 6 is transparent, and includes an inorganic sealing film 26 that covers the cathode electrode 55, an organic buffer film 27 that is an upper layer overlying the inorganic sealing film 26, and an inorganic sealing film 28 that is an upper layer overlying the organic buffer film 27. The sealing layer 6 covering the light-emitting element layer 5 inhibits foreign matter, such as water and oxygen, from penetrating to the light-emitting element layer 5.

Each of the inorganic sealing film 26 and the inorganic sealing film 28 is an inorganic insulating film, and can be configured by, for example, a silicon oxide film, a silicon nitride film, or a silicon oxynitride film, or a layered film of these, formed by CVD. The organic buffer film 27 is a transparent organic film having a flattening effect and can be formed of a coatable organic material such as acrylic. The organic buffer film 27 can be formed by, for example, ink-jet application, but a bank for stopping droplets may be provided in a non-display region.

The color filters 71, 72, and 73 are filters that are formed in an upper layer overlying the sealing layer 6 and each transmit only a wavelength of a specific color, of the white light emitted from the light-emitting element 50 of the light-emitting element layer 5. More specifically, the color filter 71 (first color filter) is provided for the subpixel corresponding to the blue pixel region BP, and is a filter that transmits only the blue light, of the white light emitted from the light-emitting element 50. The color filter 72 (second color filter) is provided for the subpixel corresponding to the green pixel region GP, and is a filter that transmits only the green light, of the white light emitted from the light-emitting element 50. The color filter 73 (third color filter) is provided for the subpixel corresponding to the red pixel region RP, and is a filter that transmits only the red light, of the white light emitted from the light-emitting element 50.

As illustrated in FIG. 2, in the display device 1, as a result of white light L1 emitted from the light-emitting element 50 passing through the color filter 71 in the blue pixel region BP, blue light L2 is emitted. Further, in the display device 1, as a result of the white light L1 emitted from the light-emitting element 50 passing through the color filter 72 in the green pixel region GP, green light L3 is emitted. Further, in the display device 1, as a result of the white light L1 emitted from the light-emitting element 50 passing through the color filter 73 in the red pixel region RP, red light L4 is emitted.

In this way, in the display device 1, high-resolution display can be performed by using the light-emitting elements 50 and the color filters 71, 72, and 73 in combination.

Further, in the display device 1, a voltage can be applied between the anode electrode 51 and the cathode electrode 55 for each of the subpixels. Further, in the display device 1, the current flowing between the anode electrode 51 and the cathode electrode 55 can be controlled, and a gray scale value of the light emitted from each of the subpixels (the red pixel region RP, the green pixel region GP, and the blue pixel region BP) can thus be controlled. With these configurations, the display device 1 can emit light of a desired color from each of the pixels.

As described above, it is known that in the light emission by the quantum dot phosphor particles, the light emission of the blue light is weaker than the light emission of the green light and the red light. Thus, in the display device 1, as illustrated in FIG. 2, the area of an opening A1 of the edge cover in the blue pixel region BP is greater than the area of an opening A2 of the edge cover in the green pixel region GP and the area of an opening A3 of the edge cover in the red pixel region RP. In this way, in one pixel, an emission amount of the blue light can be made equivalent to an emission amount of each of the red light and the green light. As a result, the light-emitting layer 53 can emit the light closer to the white light.

As described above, in the light-emitting element 50 according to the present embodiment, the light-emitting layer 53 is formed by the layer including the blue quantum dot phosphor particles 61, the green quantum dot phosphor particles 62, and the red quantum dot phosphor particles 63. Therefore, the light-emitting layer 53 can be formed by one-time ink-jet application, and is thus easy to manufacture. Further, in the light-emitting element 50, unlike in the case of PTL 1 in which the light-emitting layer is formed by a plurality of layers, it is not necessary to control the emission wavelength by adjusting the current density.

Further, in the light-emitting element 50, it is possible to (1) control the wavelength of light by controlling the particle diameters of the cores 61A to 63C of the blue quantum dot phosphor particle 61, the green quantum dot phosphor particle 62, and the red quantum dot phosphor particle 63, and (2) control color reproducibility by controlling a mixing ratio of the blue quantum dot phosphor particles 61, the green quantum dot phosphor particles 62, and the red quantum dot phosphor particles 63.

Further, in the light-emitting element layer 5, the light-emitting layer 53 is formed commonly for each of the subpixels (the red pixel region RP, the green pixel region GP, and the blue pixel region BP). As a result, since it is not necessary to form the light-emitting layer 53 for each of the subpixels, the light-emitting element layer 5 can be easily manufactured.

In the light-emitting element layer 5, the hole transport layer 52 and the electron transport layer 54 are formed commonly for each of the subpixels (the red pixel region RP, the green pixel region GP, and the blue pixel region BP). As a result, since it is not necessary to form the hole transport layer 52 and the electron transport layer 54 for each of the subpixels, the light-emitting element layer 5 can be easily manufactured.

Further, in the light-emitting element 50, the particle diameters of the blue quantum dot phosphor particle 61, the green quantum dot phosphor particle 62, and the red quantum dot phosphor particle 63 are substantially the same as a whole. In this way, when the light-emitting layer 53 is applied using the ink-jet method, the blue quantum dot phosphor particles 61, the green quantum dot phosphor particles 62, and the red quantum dot phosphor particles 63 can be uniformly dispersed. As a result, the light-emitting element 50 can emit the white light with no color unevenness.

Note that in the light-emitting element according to an aspect of the present invention, the hole transport layer 52, the light-emitting layer 53, and the electron transport layer 54 may be formed for each of the subpixels.

Further, the blue quantum dot phosphor particle 61, the green quantum dot phosphor particle 62, and the red quantum dot phosphor particle 63 according to an aspect of the present invention may each be a two-component core type, a three-component core type, a four-component core type, a core multi-shell type, a doped nanoparticle, or an inclined quantum dot phosphor particle.

### Manufacturing Method for Core-Shell Type Quantum Dot

Next, an example of a manufacturing method for the blue quantum dot phosphor particles 61, the green quantum dot phosphor particles 62, and the red quantum dot phosphor particles 63 will be described.

First, the manufacturing method for the blue quantum dot phosphor particle 61 will be described, the blue quantum dot phosphor particle 61 being provided with a nanoparticle core (the core 61A) that is formed of InP and has a particle diameter of 1 nm, a shell layer (the shell 61B) that is formed of ZnS and has a film thickness of 1.5 nm, and a modified organic compound formed of hexadecylamine (HDA).

When manufacturing the above-described blue quantum dot phosphor particle 61, first, 29 ml of 1-octadecene solution containing 0.1 mmol of indium trichloride and 0.5 mmol of HDA is heated to 230° C. To this solution, by adding 1 ml of 1-octadecene solution containing 0.1 mmol of tris (trimethylsilylphosphine) and causing a reaction for 5 minutes, the nanoparticle core (the core 61A) formed of InP is synthesized.

Next, 30 ml of 1-octadecene solution containing 3.5 mmol of zinc acetate and 3.5 mmol of sulfur, which is a raw material of the shell 62B, is added to the solution and is caused to react for 8 hours at 200° C. As a result, the shell layer (the shell 61B) formed of ZnS is synthesized, and it is possible to manufacture the blue quantum dot phosphor particle 61 having an overall configuration of InP (the nanoparticle core, the core 61A)/ZnS (the shell layer, 62B)/HDA (the modified organic compound), in which the particle of the core 61A is 1 nm and the film thickness of the shell 61B is 1.5 nm.

The particle diameter of the blue quantum dot phosphor particle 61 manufactured by the above-described method is adjusted so that the emission wavelength of an InP crystal forming the core 61A is 480 nm, and thus the blue quantum dot phosphor particle 61 emits the blue light.

Further, by adjusting the reaction time when synthesizing the nanoparticle core formed of InP and the mixing amounts of zinc acetate and sulfur when synthesizing the shell layer, the green quantum dot phosphor particle 62 whose luminescent color is green and the red quantum dot phosphor particle 63 whose luminescent color is red can be manufactured.

Specifically, by setting the reaction time when synthesizing the nanoparticle core to 10 minutes and setting each of the mixing amounts of zinc acetate and sulfur when synthesizing the shell layer to 3.0 mmol, the green quantum dot phosphor particle 62 can be manufactured in which the emission wavelength of the InP crystal forming the core 62A is 530 nm, the particle of the core 62A is 2 nm, and the film thickness of the shell 62B is 1 nm.

Further, by setting the reaction time when synthesizing the nanoparticle core to 15 minutes and setting each of the mixing amounts of zinc acetate and sulfur when synthesizing the shell layer to 2.0 mmol, the red quantum dot phosphor particles 63 can be manufactured in which the emission wavelength of the InP crystal forming the core 63A is 630 nm, the particle of the core 63A is 3 nm, and the film thickness of the shell 63B is 0.5 nm.

### Second Embodiment

Another embodiment of the present invention will be described below with reference to the drawings. For convenience of description, members having the same function as the members stated in the embodiment described above are denoted by the same reference signs, and a description thereof is omitted.

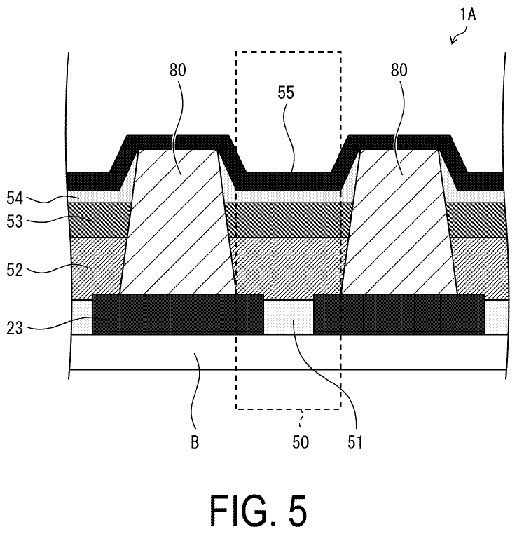

FIG. 5 is a cross-sectional view illustrating a configuration of a display region of a display device 1A according to the present embodiment. As illustrated in FIG. 5, in the display device 1A, the hole transport layer 52, the light-emitting layer 53, and the electron transport layer 54 are formed for each of the light-emitting elements 50. Further, a water repellent bank 80 is provided in an upper layer overlying the anode electrode 51 between each of the light-emitting elements 50. The water repellent bank 80 is a light blocking member having light blocking properties.

Since the light-emitting layer 53 is partitioned by the water repellent bank 80 for each of the subpixels in the display device 1A, of the light emitted from the light-emitting layer 53 of each of the subpixels, light emitted in the lateral direction can be blocked by the water repellent bank 80. As a result, it is possible to prevent light emitted from between the subpixels adjacent to each other from mixing together (specifically, it is possible to prevent an occurrence of color mixing.

The present invention is not limited to each of the embodiments described above, and various modifications may be made within the scope of the claims. Embodiments obtained by appropriately combining technical approaches disclosed in each of the different embodiments also fall within the technical scope of the present invention. Moreover, novel technical features can be formed by combining the technical approaches disclosed in the embodiments.

### Supplement

A light-emitting element (50) according to a first aspect of the present invention is a light-emitting element including a cathode electrode (55), an anode electrode (51), and a light-emitting layer (53) formed between the cathode electrode and the anode electrode. The light-emitting layer is formed by a layer including a first quantum dot particle (the blue quantum dot phosphor particles 61) that emits blue light as a result of combining electrons supplied from the cathode electrode and positive holes supplied from the anode electrode, a second quantum dot phosphor particle (the green quantum dot phosphor particle 62) that emits green light as a result of combining the electrons supplied from the cathode electrode and the positive holes supplied from the anode electrode, and a third quantum dot phosphor particle (the red quantum dot phosphor particle 63) that emits red light as a result of combining the electrons supplied from the cathode electrode and the positive holes supplied from the anode electrode.

In the light-emitting element according to a second aspect of the present invention, in the first aspect, the first to third quantum dot phosphor particles are formed of at least one material selected from the group consisting of CdS, CdSe, CdTe, ZnS, ZnSe, ZnTe, InN, InP, InAs InSb, AlP, AlS, AlAs, AlSb, GaN, GaP, GaAs, GaSb, PbS, PbSe, Si, Ge, MgS, MgSe, and MgTe.

In the light-emitting element according to a third aspect of the present invention, in the first aspect or the second aspect, the first to third quantum dot phosphor particles contain InP.

In the light-emitting element according to a fourth aspect of the present invention, in any one of the first to third aspects, each of the first to third quantum dot phosphor particles has a core-shell structure formed by the core 61A to 63A and the shell 61B to 63B covering a periphery of the core, and by adjusting thicknesses of the shells, the first to third quantum dot phosphor particles have substantially the same particle diameter.

In the light-emitting element according to a fifth aspect of the present invention, in the fourth aspect, a particle diameter of the core of the first quantum dot phosphor particle is smaller than a particle diameter of the core of the third quantum dot phosphor particle, and the thickness of the shell of the first quantum dot phosphor particle is greater than the thickness of the shell of the third quantum dot phosphor particle.

In the light-emitting element according to a sixth aspect of the present invention, in any one of the first to fifth aspects, the particle diameters of the first to third quantum dot phosphor particles are in a range of from 0.1 to 100 nm.

In the light-emitting element according to a seventh aspect of the present invention, in any one of the first to sixth aspects, in the light-emitting layer, a concentration of the first quantum dot phosphor particles is higher than a concentration of the second quantum dot phosphor particles and a concentration of the third quantum dot phosphor particles.

A display device (1, 1A) according to an eighth aspect of the present invention is a display device including a plurality of the light-emitting elements according to any one of the first to seventh aspects, and a light-emitting element layer (5) in which a plurality of subpixels are formed by an edge of one of the cathode electrode and the anode electrode corresponding to each of the light-emitting elements being covered by an edge cover (23), one of a first color filter (the color filter 71) that transmits blue light, a second color filter (the color filter 72) that transmits green light, and a third color filter (the color filter 73) that transmits red light is provided for each of the plurality of subpixels, and an opening area of the edge cover in the subpixel provided with the first color filter is larger than an opening area of the edge cover in the subpixel provided with one of the second color filter and the third color filter.

In the display device according to a ninth aspect of the present invention, in the eighth aspect, in the light-emitting element layer, the light-emitting layer is formed commonly for the subpixels provided with the first to third color filters.

In the display device according to a tenth aspect of the present invention, in the eighth aspect or the ninth aspect, the light-emitting element includes the hole transport layer 52 and the electron transport layer 54, and in the light-emitting element layer, the hole transport layer and the electron transport layer are formed commonly for the subpixels provided with the first to third color filters.

In the display device according to an eleventh aspect of the present invention, in the eighth aspect, the light-emitting layer is partitioned by a light blocking member for each of the subpixels.

### REFERENCE SIGNS LIST

1, 1A Display device
5 Light-emitting element layer
23 Edge cover
50 Light-emitting element
51 Anode electrode
52 Hole transport layer
53 Light-emitting layer
54 Electron transport layer
55 Cathode electrode
61 Blue quantum dot phosphor particle (first quantum dot phosphor particle)

### 61A, 62A, 62A Core

### 61B, 62B, 63B Shell

62 Green quantum dot phosphor particle (second quantum dot phosphor particle)
63 Red quantum dot phosphor particle (third quantum dot phosphor particle)
71 Color filter (first color filter)
72 Color filter (second color filter)
73 Color filter (third color filter)
80 Water repellent bank (light blocking member)

1. A light-emitting element comprising:
one or more cathode electrodes;
one or more anode electrodes; and
a light-emitting layer formed between the cathode electrode and the anode electrode,
wherein the light-emitting layer is formed by a layer including
a first quantum dot phosphor particle that emits blue light by as a result of combining electrons supplied from the cathode electrode and positive holes supplied from the anode electrode,
a second quantum dot phosphor particle that emits green light as a result of combining the electrons supplied from the cathode electrode and the positive holes supplied from the anode electrode, and
a third quantum dot phosphor particle that emits red light as a result of combining the electrons supplied from the cathode electrode and the positive holes supplied from the anode electrode.

2. The light-emitting element according to claim 1,
wherein the first to third quantum dot phosphor particles are formed of at least one material selected from a group consisting of CdS, CdSe, CdTe, ZnS, ZnSe, ZnTe, InN, InP, InAs InSb, AlP, AlS, AlAs, AlSb, GaN, GaP, GaAs, GaSb, PbS, PbSe, Si, Ge, MgS, MgSe, and MgTe.

3. The light-emitting element according to claim 1,
wherein either one of the first to third quantum dot phosphor particles contain InP.

4. The light-emitting element according to claim 1,
wherein each of the first to third quantum dot phosphor particles has a core-shell structure formed by a core and a shell covering a periphery of the core, and
by adjusting thicknesses of the shells, the first to third quantum dot phosphor particles have substantially a same particle diameter.

5. The light-emitting element according to claim 4,
wherein a particle diameter of the core of the first quantum dot phosphor particle is smaller than a particle diameter of the core of the third quantum dot phosphor particle, and
the thickness of the shell of the first quantum dot phosphor particle is greater than the thickness of the shell of the third quantum dot phosphor particle.

6. The light-emitting element according to claim 1,
wherein the particle diameters of the first to third quantum dot phosphor particles are in a range of from 0.1 to 100 nm.

7. The light-emitting element according to claim 1,
wherein in the light-emitting layer, a concentration of the first quantum dot phosphor particles is higher than a concentration of the second quantum dot phosphor particles and a concentration of the third quantum dot phosphor particles.

8. A display device comprising:
a plurality of the light-emitting elements according to claim 1; and
a light-emitting element layer in which a plurality of subpixels are formed by an edge of one of the cathode electrode and the anode electrode corresponding to each of the light-emitting elements being covered by an edge cover,
wherein one of a first color filter that transmits blue light, a second color filter that transmits green light, and a third color filter that transmits red light is provided for each of the plurality of subpixels, and
an opening area of the edge cover in the subpixel provided with the first color filter is larger than an opening area of the edge cover in the subpixel provided with one of the second color filter and the third color filter.

9. The display device according to claim 8,
wherein in the light-emitting element layer, the light-emitting layer is formed commonly for the subpixels provided with the first to third color filters.

10. The display device according to claim 8,
wherein the light-emitting element includes a hole transport layer and an electron transport layer, and
in the light-emitting element layer, the hole transport layer and the electron transport layer are formed commonly for the subpixels provided with the first to third color filters.

11. The display device according to claim 8,
wherein the light-emitting layer is partitioned by a light blocking member for each of the subpixels.

12. A display device comprising:
a plurality of the light-emitting elements according to claim 1 wherein
the one or more anode electrodes comprise three or more anode electrodes separated from each other,
the light-emitting layer is disposed over three or more anode electrodes,
the one or more cathode electrodes comprise one cathode electrode over the three or more anode electrodes and the light-emitting layer.

13. The display device according to claim 12, further comprising
edge covers separating each two of three or more anode electrodes,
areas of one of the three or more anode electrodes exposed from the edge covers are different.

14. The display device according to claim 13, further comprising
a first color filter that transmits blue light, is arranged on a light extraction side and overlays on a first portion of the light-emitting layer,
a second color filter that transmits green light, is arranged on a light extraction side and overlays on a second portion of the light-emitting layer and not overlays the first portion of the light-emitting layer,
a third color filter that transmits green light, is arranged on a light extraction side and overlays on a third portion of the light-emitting layer and not overlays the first portion and the second portion of the light-emitting layer,
an area exposed form the edge covers of one of three or more anode electrodes that overlays the first color filter is larger than other areas exposed from the edge covers of one of three or more anode electrodes that overlays the second color filter and the third color filter.

15. A display device comprising:
a plurality of the light-emitting elements according to claim 1 wherein
the one or more cathode electrodes comprise three or more cathode electrodes separated from each other,
the light-emitting layer is disposed over three or more anode electrodes,
the one or more anode electrodes comprise one anode electrode over the three or more cathode electrodes and the light-emitting layer.

16. The display device according to claim 15, further comprising
edge covers separating each two of three or more cathode electrodes,
areas of one of the three or more cathode electrodes exposed from edge covers are different.

17. The display device according to claim 16, further comprising
a first color filter that transmits blue light, is arranged on a light extraction side and overlays on a first portion of the light-emitting layer,
a second color filter that transmits green light, is arranged on a light extraction side and overlays on a second portion of the light-emitting layer and not overlays the first portion of the light-emitting layer,
a third color filter that transmits green light, is arranged on a light extraction side and overlays on a third portion of the light-emitting layer and not overlays the first portion and the second portion of the light-emitting layer,
an area exposed form the edge covers of one of three or more cathode electrodes that overlays the first color filter is larger than other areas exposed from the edge covers of one of three or more anode electrodes that overlays the second color filter and the third color filter.
